(19) United States
(12) Patent Application Publication
(10) Pub. No.: US 2026/0081114 A1
(43) Pub. Date: Mar. 19, 2026

(54) APPARATUS FOR PROCEEDING SURFACE HEAT TREATMENT BY PLASMA AND METHOD USING THE SAME

(71) Applicant: Industrial Technology Research Institute, Hsinchu (TW)

(72) Inventors: JUI-MEI HSU, Hsinchu County (TW); YU-SHENG LEE, New Taipei city (TW)

(21) Appl. No.: 19/008,043

(22) Filed: Jan. 2, 2025

(30) Foreign Application Priority Data
Sep. 16, 2024 (TW) 113135149

(51) Int. Cl. H01J 37/32

(52) U.S. Cl. CPC H01J 37/32449

(57) ABSTRACT

An apparatus for proceeding surface heat treatment by plasma and method using the same. The apparatus includes a body with first flow channel, second flow channel, third flow channel and slot. The first flow channel has a first end and a second end relatively along a first axis. The second flow channel has a third end and a fourth end relatively along the first axis. The third end connects with the second end and inner diameter of the second flow channel is bigger than inner diameter of the second end. The third flow channel has a fifth end and a sixth end relatively along a second axis. The fifth end connects with the second flow channel and the six end penetrates through the body. Angle between the first axis and the second axis is equal or bigger than 0 degree. The slot penetrates through the body along a third axis.

### CROSS REFERENCE TO RELATED APPLICATION

This application claims the benefits of Taiwan application Serial No. 113135149, filed on Sep. 16, 2024, the disclosures of which are incorporated by references herein in its entirety.

### TECHNICAL FIELD

The present disclosure relates to the technical field of heating technology, and in particular, to an apparatus that uses plasma air flow control to perform heat treatment on edge surfaces of a workpiece and a method of using the same.

### BACKGROUND

The workpieces used in each technical field are made of different materials, such as glass, ceramics, metals, etc. After the workpieces are cut to the required size, depending on the needs of the product, grinding is usually used to define the shape of the edges of workpieces, and wet polishing is used to smooth the surface of the edges.

To achieve high smoothness, multiple abrasive polishing processes are required, which is labor-intensive, time-consuming and costly. This technology develops plasma heating to melt surface materials and smooth them through surface tension. However, if the heating temperature range or temperature gradient is not well controlled, it will lead to thermal deformation of the directly heated portions of the workpiece. Alternatively, if the directly heated portion of the workpiece has too large a temperature difference with the neighboring portions, it will lead to the workpiece being broken by excessive thermal stress.

### SUMMARY

In one embodiment, the present disclosure proposes a device for surface heat treatment by plasma, comprising:
a body;
a first flow channel, provided in the body and having a first end and a second end relatively parallel to a first axis, wherein the first end penetrates through the body for connecting to a plasma generation source;
a second flow channel, provided in the body and having a third end and a fourth end relatively parallel to the first axis, wherein the third end is connected with the second end, an inner diameter of the second flow channel is larger than an inner diameter of the second end, the fourth end does not penetrate through the body, and a projection range of the first flow channel parallel to the first axis falls within a projection range of the second flow channel parallel to the first axis;
a third flow channel, provided in the body and having a fifth end and a sixth end relatively parallel to a second axis, the fifth end is connected with the second flow channel, the sixth end penetrates through the body, an included angle is formed between the second axis and the first axis, the included angle is ≥0 degrees, and the first flow channel, the second flow channel, and the third flow channel form a continuous channel; and
a slit, inserted into the body from a surface with the sixth end parallel to the second axis and reaching a depth into the second flow channel, wherein the slit is parallel to the third axis and penetrates through the relative two surfaces of the body, the third axis and the first axis are perpendicular to each other, a projection range of the slit parallel to the third axis falls within a projection range of the third flow channel parallel to the third axis, the slit is formed by a first inner wall and a second inner wall parallel with each other, an inclination angle of the first inner wall and the second inner wall is parallel to the second axis, a width of the slit is formed between the first inner wall and the second inner wall, the slit allows a workpiece to enter the slit parallel to the third axis.

In another embodiment, the present disclosure provides a method of using the aforementioned apparatus, comprising:
The workpiece is carried through the slit, wherein the edge to be processed of the workpiece is located in the second flow channel, and the edge to be processed has a first side edge and a second side edge relatively;
A plasma air flow is provided by the plasma generation source to enter the first flow channel from the first end, then enters the second flow channel and flows to the edge of the workpiece;
After the plasma air flow contacts the workpiece, it is split into a first plasma split flow and a second plasma split flow; and
The first plasma split flow flows to the first side edge and performs heat treatment on a surface of the first side edge, and the second plasma split flow flows to the second side edge and performs heat treatment on the second side edge at the same time.

### BRIEF DESCRIPTION OF THE DRAWINGS

FIG. 1 is a schematic diagram of the exterior three-dimensional structure of one embodiment of the apparatus of the present disclosure.

FIG. 2 is a schematic view of the front view structure of the embodiment of FIG. 1.

FIG. 3 is a schematic view of the top view structure of the embodiment of FIG. 1.

FIG. 4 is a schematic view of the bottom elevation view structure of the embodiment of FIG. 1.

FIG. 5 is a schematic cross-sectional structural diagram of the A-A section in FIG. 3.

FIG. 6 is a schematic cross-sectional structural diagram of the embodiment of FIG. 1 when applied to a workpiece.

FIG. 7 is an enlarged structural diagram of portion B of FIG. 6.

FIG. 8 is a schematic cross-sectional structural diagram of another embodiment of the apparatus of the present disclosure when applied to a workpiece.

FIGS. 9 and 10 are schematic cross-sectional structural diagrams of other two embodiments of the apparatus of the present disclosure when applied to a workpiece.

FIGS. 11 and 12 are schematic diagrams of the three-dimensional structure of the apparatus of the present disclosure in which the processing portion is replaceable.

FIGS. 13 to 16 are schematic cross-sectional structural diagrams of the apparatus of the present disclosure replacing different processing portions.

FIG. 17 is a step flow chart of one embodiment of the method of the present disclosure.

### DETAILED DESCRIPTION

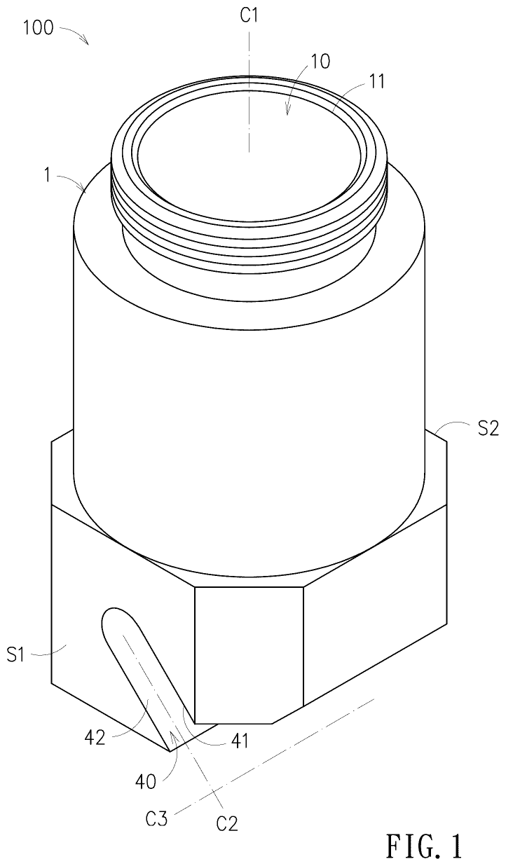

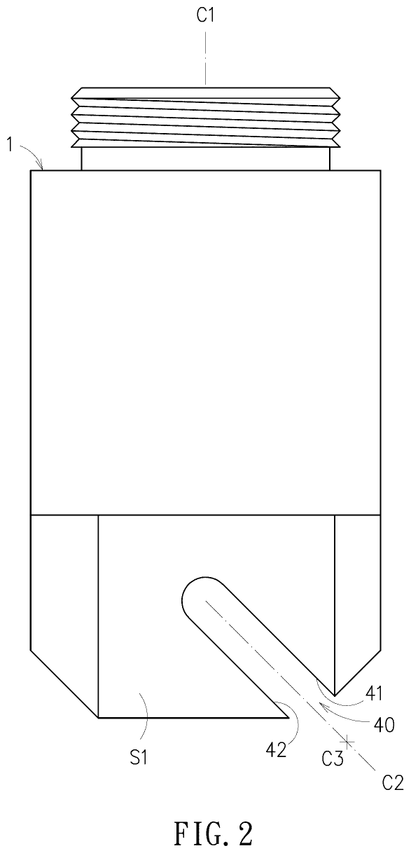

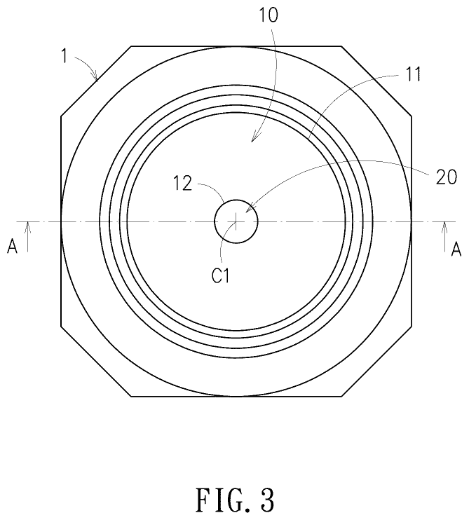

Please refer to FIGS. 1 to 5. The present disclosure provides an apparatus 100 for surface heat treatment by using plasma. The apparatus 100 includes a body 1 in which a first flow channel 10, a second flow channel 20, a third flow channel 30 and a slit 40 are provided.

The body 1 is made of a high temperature resistant material, which in the case of plasma heat treatment can be, for example, in the range of 600 degrees Celsius to 1600 degrees Celsius.

Please refer to FIGS. 1, 3 and 5. The first flow channel 10 is parallel to a first axis C1 and has a first end 11 and a second end 12 relatively. The first end 11 penetrates through the body 1 and is connected to a plasma generation source (not shown in the figure).

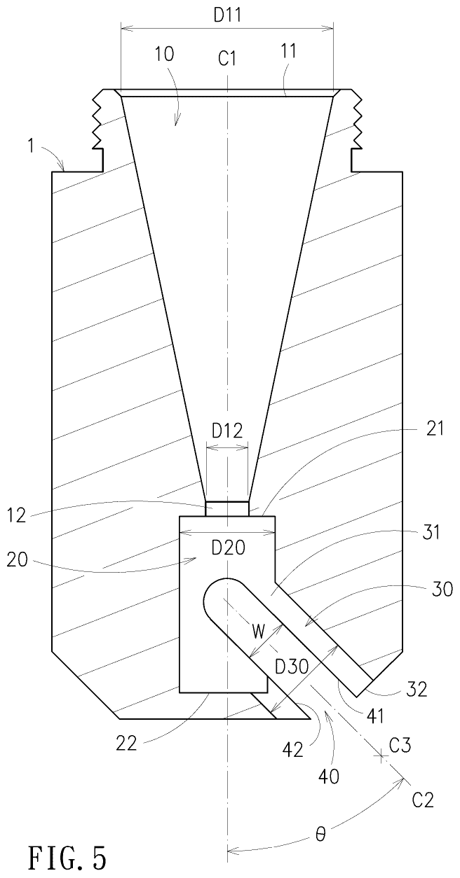

As shown in FIG. 5, the inner diameter D11 of the first end 11 is larger than the inner diameter D12 of the second end 12, and the first flow channel 10 is tapered, but is not limited thereto.

The inner diameter D12 of the second end 12 could be, for example, 2 mm to 6 mm, but is not limited thereto.

Please refer to FIG. 5. The second flow channel 20 is parallel to the first axis C1 and has a third end 21 and a fourth end 22 relatively. The third end 21 is connected with the second end 12, and the fourth end 22 does not penetrate through the body 1. The inner diameter D20 of the second flow channel 20 is larger than the inner diameter D12 of the second end 12.

The projection range of the first flow channel 10 parallel to the first axis C1 falls within the projection range of the second flow channel 20 parallel to the first axis C1. In this embodiment, the first flow channel 10 and the second flow channel 20 are arranged coaxially, but are not limited thereto.

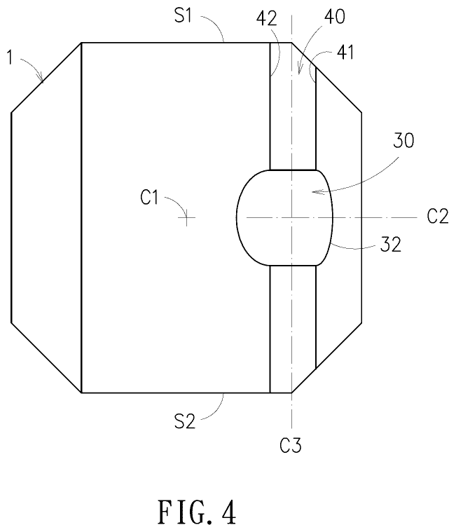

Please refer to FIG. 4 and FIG. 5. The third flow channel 30 is parallel to a second axis C2 and has a fifth end 31 and a sixth end 32 relatively. The fifth end 31 is connected with the second flow channel 20, and the sixth end 32 penetrates through the body 1. The first flow channel 10, the second flow channel 20, and the third flow channel 30 form a continuous channel.

Please refer to FIG. 5. An included angle θ is formed between the second axis C2 and the first axis C1, with the included angle θ≥0 degrees. Furthermore, the included angle θ can be, for example, 0 degrees to 90 degrees. The included angle θ of the embodiment illustrated in FIGS. 1 to 5 is 45 degrees.

Please refer to FIGS. 1, 2, 4 and 5. The slit 40 is inserted into the body 1 from the surface of the body 1 with a sixth end 32 parallel to the second axis C2 and reaches the depth into the second flow channel 20. The slit 40 is parallel to the third axis C3 extending and penetrating through the first surface S1 and a second surface S2 relatively of the body 1. The third axis C3 and the first axis C1 are perpendicular to each other.

The projection range of the slit 40 parallel to the third axis C3 falls within the projection range of the third flow channel 30 parallel to the third axis C3. Furthermore, the center of the projection range of the slit 40 parallel to the third axis C3 may fall on the center of the projection range of the third flow channel 30 parallel to the third axis C3. If the third flow channel 30 is in the shape of a circular tube, the center of the projection range of the slit 40 parallel to the third axis C3 falls on the axis line of the third flow channel 30.

The slit 40 consists of a first inner wall 41 and a second inner wall 42 that are parallel to each other. The inclination angle of the first inner wall 41 and the second inner wall 42 is parallel to the second axis C2. The width W of the slit 40 is formed between the first inner wall 41 and the second inner wall 42.

The design dimensions of the first flow channel 10, the second flow channel 20, the third flow channel 30 and the slit 40 are designed based on actual needs.

Please refer to FIG. 5. The relationship between the width W of the slit 40 and the thickness of the workpiece can be, for example: (width W)>(thickness of the workpiece+1 mm). The width W complies with the principle that the workpiece can pass through without touching the first inner wall 41 or the second inner wall 42.

The inner diameter D30 of the third flow channel 30 is larger than the width W of the slit 40.

The relationship of the inner diameter D30 of the third flow channel 30, the inner diameter D20 of the second flow channel 20 and the inner diameter D12 of the second end 12 of the first flow channel 10 may be, for example: (inner diameter D30 of the third flow channel 30)=(inner diameter D20 of the second flow channel 20)>(inner diameter D12 of the second end 12+2 mm).

For example, if the inner diameter D12 of the second end 12 of the first flow channel 10 is 2 mm, the inner diameter D20 of the second flow channel 20 may be 5 mm, and the inner diameter D30 of the third flow channel 30 may be 5 mm. If the thickness of workpiece is 1 mm, the width W of the slit 40 may be 2.5 mm.

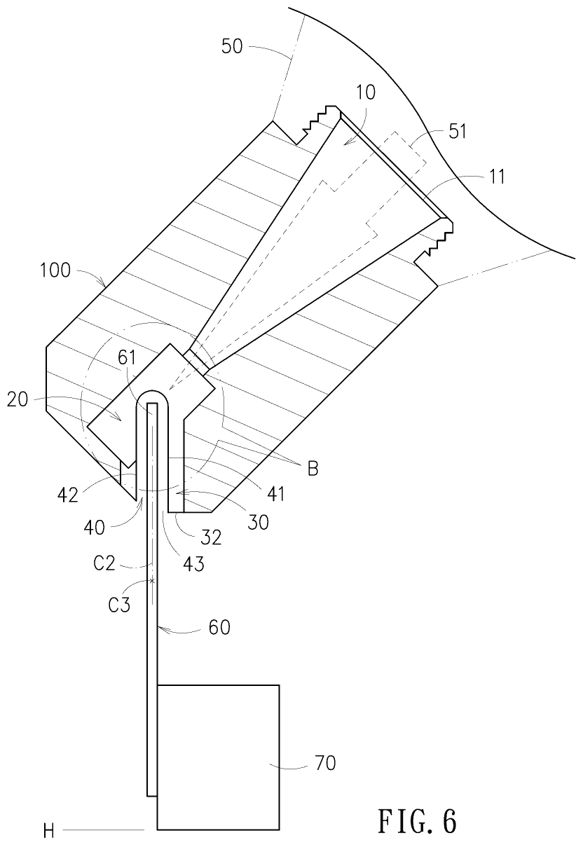

Please refer to FIG. 6. When the apparatus 100 is used, the second axis C2 is arranged perpendicularly to the horizontal plane H, so that the opening end 43 of the slit 40 is vertically facing toward the horizontal plane H. The first end 11 of the apparatus 100 is connected to a plasma generation source 50, and the plasma generation source 50 is used to provide a plasma air flow 51.

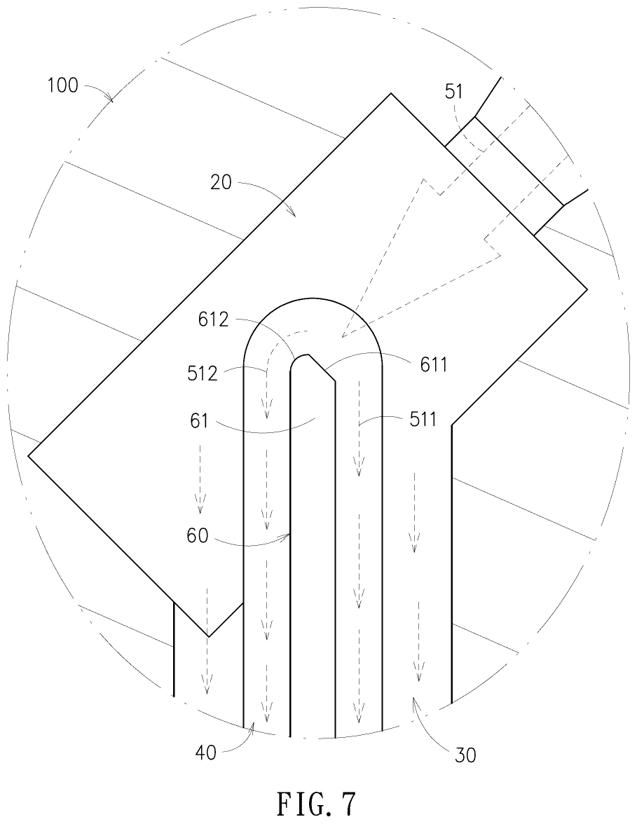

Please refer to FIGS. 6 and 7. The workpiece 60 is carried and driven by the fixture 70 for moving, so that the workpiece 60 is parallel with the third axis C3 and enters the slit 40, and the edge 61 of the workpiece 60 to be processed is located within the second flow channel 20. The edge 61 has a first side edge 611 and a second side edge 612 relatively. The plasma air flow 51 enters the first flow channel 10 through the first end 11, then enters the second flow channel 20, and flows toward the edge 61 of the workpiece 60. There is no limit to the distance between the first side edge 611 and the second side edge 612 of the workpiece 60 and the adjacent first inner side wall 41 and the second inner side wall 42, as long as they do not touch each other.

It should be noted that, the type of fixture that carries and drives the workpiece 60 is not limited thereto. For example, it may be a vacuum suction method, which utilizes a vacuum to cause the workpiece to be sucked on the fixture, or a clamping method, which causes the workpiece to be clamped to the fixture. The method used to drive the fixture is not limited, and it may be mechanically constructed or driven by an electronic device.

Please refer to FIG. 7. After the plasma air flow 51 contacts the edge 61 of the workpiece 60, it will be split into a first plasma split flow 511 and a second plasma split flow 512. The first plasma split flow 511 flows to the first side edge 611 and performs heat treatment on the surface of the first side edge 611, and the second plasma split flow 512 flows to the second side edge 612 and performs heat treatment on the second side edge 612 at the same time.

Please refer to FIG. 7. When the plasma air flow 51 flows to the workpiece 60, the workpiece 60 creates resistance to the plasma air flow 51 so that a portion of the plasma air flow (i.e., the first plasma split flow 511) will flow to the first side edge 611, while another portion of the plasma air flow (i.e., the second plasma split flow 512) will flow around the workpiece 60 to the second side edge 612.

Compared with the thermal effect of the second plasma split flow 512 on the second side edge 612, since the first side edge 611 faces the plasma air flow 51 directly, the thermal effect of the first plasma split flow 511 on the first side edge 611 will be greater. With this characteristic, asymmetric heat treatment can be executed on the surface of the first side edge 611 and the second side edge 612 relative to the edge 61 of the workpiece 60.

The first plasma split flow 511 and the second plasma split flow 512 are filled in the third flow channel 30 at the same time, so that the third flow channel 30 accumulates a larger amount of the first plasma split flow 511 and the second plasma split flow 512 to enhance the heat treatment efficiency. The first plasma split flow 511 and the second plasma split flow 512 after heat treatment then flow out of the apparatus 100 through the sixth end 32 of the third flow channel 30 (as shown in FIG. 6) and the opening end 43 of the slit 40 (as shown in FIG. 6).

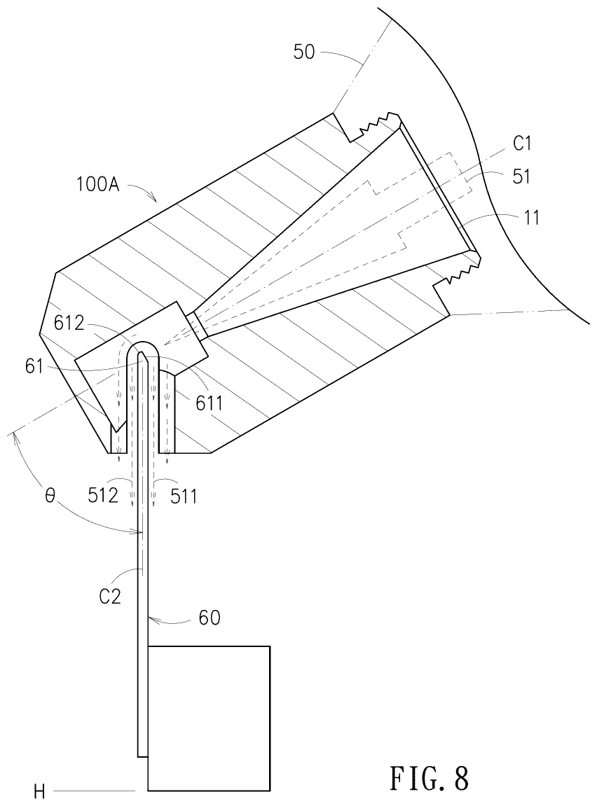

Please refer to the embodiment shown in FIG. 8. The difference between the embodiment shown in FIG. 5 is that the angle θ between the second axis C2 and the first axis C1 of the apparatus 100A is 60 degrees.

When the apparatus 100A is used, it is set with the second axis C2 perpendicular to the horizontal plane H. The first end 11 of the apparatus 100A is connected to a plasma generation source 50, and the plasma generation source 50 is used to provide a plasma air flow 51. After the plasma air flow 51 contacts the edge 61 of the workpiece 60, it will split into a first plasma split flow 511 and a second plasma split flow 512 to perform asymmetric heat treatment on the first side edge 611 and the second side edge 612 simultaneously.

Compared with FIG. 6, FIG. 8 is used with a larger inclination angle (closer to the horizontal plane H), but is used in the same way.

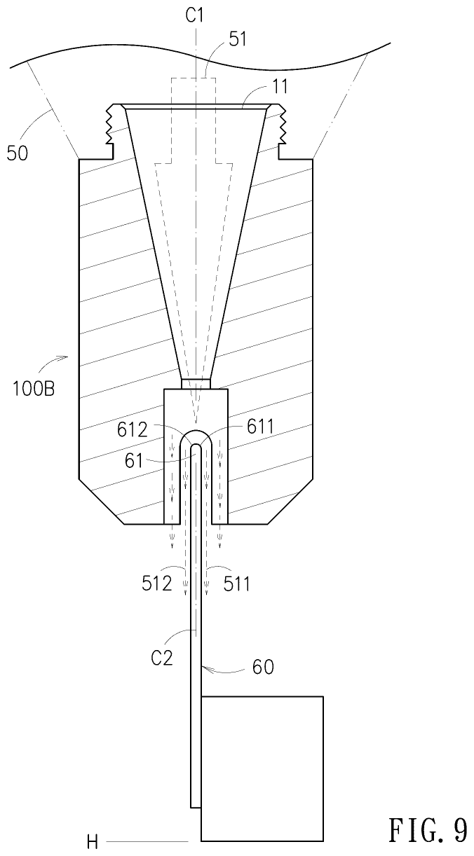

Please refer to the embodiment shown in FIG. 9. The difference between the embodiment shown in FIG. 5 or FIG. 8 is that the second axis C2 of the apparatus 100B is coaxial with the first axis C1. In other words, the included angle between the second axis C2 and the first axis C1 is 0 degree.

When the apparatus 100B is used, it is set with the second axis C2 perpendicular to the horizontal plane H. The first end 11 of the apparatus 100B is connected to a plasma generation source 50, and the plasma generation source 50 is used to provide a plasma air flow 51. After the plasma air flow 51 contacts the edge 61 of the workpiece 60, it will split into a first plasma split flow 511 and a second plasma split flow 512, and perform heat treatment on the first side edge 611 and the second side edge 612 simultaneously.

Since the second axis C2 is coaxial with the first axis C1, the first plasma split flow 511 and the second plasma split flow 512 act on the first side edge 611 and the second side edge 612 in substantially equal amounts. Accordingly, the morphology of the first side edge 611 and the second side edge 612 after heat treatment is symmetrical.

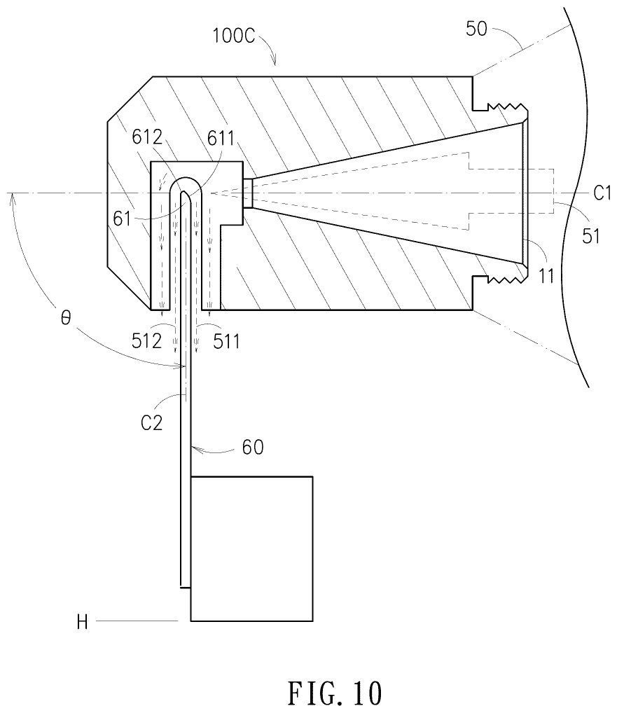

Please refer to the embodiment shown in FIG. 10. The difference between the embodiment shown in FIG. 5 or FIG. 8 is that the included angle θ between the second axis C2 and the first axis C1 of the apparatus 100C is 90 degrees.

When the apparatus 100C is used, it is set with the second axis C2 perpendicular to the horizontal plane H. The first end 11 of the apparatus 100C is connected to a plasma generation source 50, and the plasma generation source 50 is used to provide a plasma air flow 51. After the plasma air flow 51 contacts the edge 61 of the workpiece 60, it will split into a first plasma split flow 511 and a second plasma split flow 512, and perform asymmetric heat treatment on the first side edge 611 and the second side edge 612 simultaneously.

The different embodiments shown in FIGS. 5, 8 to 10 are used to illustrate that when the included angle θ between the second axis C2 and the first axis C1 is different, symmetrical or asymmetric heat treatment can be performed with plasma on the first side edge 611 and the second side edge 612 relative to the edge 61 of the workpiece 60. In addition, the first side edge 611 and the second side edge 612 of the workpiece 60 have different morphologies according to different included angle θ. Users can select different apparatuses based on actual needs.

It should be emphasized that although the structures of the different embodiments in FIGS. 6, 8 to 10 are slightly different, they can all achieve the effect of heat treatment on edge surfaces of the workpiece. In addition, since the edge of the workpiece 60 extends into the slit 40 of the apparatuses 100 to 100C, the edge 61 of the workpiece 60 is located in the second flow channel 20, and the apparatuses 100 to 100C form an outer cover on the edge 61 of the workpiece 60. Compared to the conventional open plasma heat treatment method, the surface heat treatment apparatus using plasma provided by the present disclosure can retain the heat of plasma gas flow and reduce energy consumption.

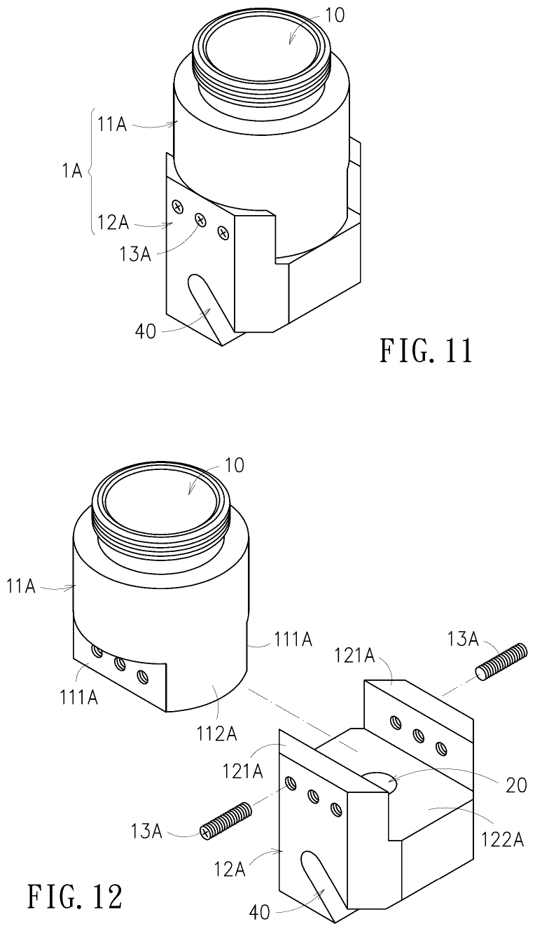

Please refer to FIGS. 11 to 13, the body 1A includes a first portion 11A and a second portion 12A.

The first flow channel 10 is provided in the first portion 11A. A first recess portion 111A is provided on two relative sides of the first portion 11A, and a first convex portion 112A is formed between the two first recess portions 111A.

The second flow channel 20, the third flow channel 30 and the slit 40 are provided in the second portion 12A. A second convex portion 121A is provided on two relative sides of the second portion 12A, and a second recess portion 122A is formed between the two second convex portions 121A.

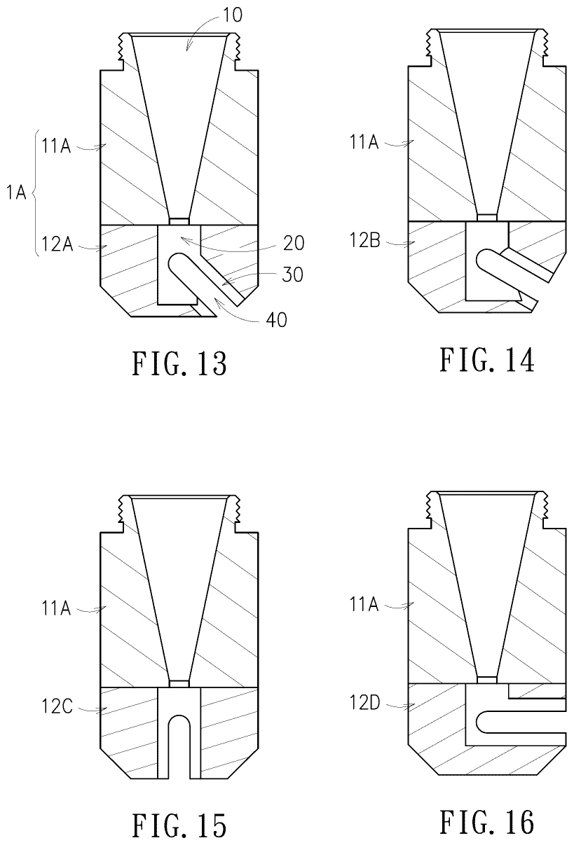

The first convex portion 112A is fitted with the second recess portion 122A, and each first recess portion 111A is fitted with a second convex portion 121A and screwed with a bolt 13A. This constitutes a structure similar to that of FIG. 5, except that the body 1A of the embodiment shown in FIGS. 12 to 14 consists of a first portion 11A and a second portion 12A in FIG. 13 or a second portion 12B in FIG. 14 that are separably coupled.

It can be understood by persons skilled in the art of this disclosure that the bolt 13A may be replaced by a structure such as a clip or a hook.

Please refer to FIGS. 14 to 16, by utilizing the detachable structure shown in FIG. 12, the same first portion 11A can be used in association with the second portions 12B, 12C, and 12D of different specifications. For example, the second portions 12B, 12C, and 12D in different configurations with the included angles of 45 degrees, 0 degrees, and 90 degrees are illustrated in FIGS. 14 to 16 respectively.

This not only enhances the convenience of the manufacturing process, but also reduces the manufacturing cost of the device by allowing the replacement of different bodies for different sizes of workpieces.

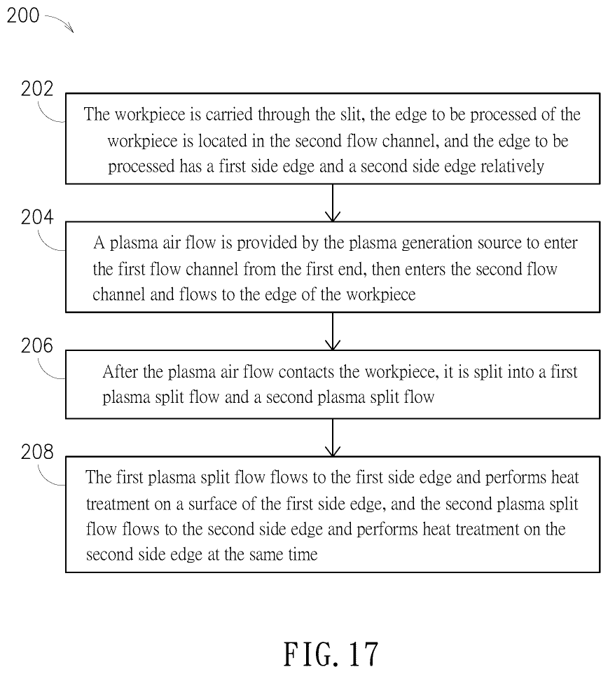

Please refer to FIG. 17. According to the apparatus 100 for surface heat treatment using plasma provided by the present disclosure, a process 200 for a method of using the apparatuses can be summarized in the following steps. Please also refer to FIG. 6.
Step 202: The workpiece 60 parallel to the third axis C3 is carried through the slit 40, and the edge 61 to be processed of the workpiece 60 is located in the second flow channel 20, and the edge 61 has a first side edge 611 and a second side edge 612 relatively.
Step 204: The plasma air flow 51 provided by the plasma generation source 50 enters the first flow channel 10 from the first end 11, then enters the second flow channel 20 and flows to the edge 61 of the workpiece 60.
Step 206: After the plasma air flow 51 contacts the workpiece 60, it is split into a first plasma split flow 511 and a second plasma split flow 512.
Step 208: The first plasma split flow 511 flows to the first side edge 611 and performs heat treatment on the surface of the first side edge 611, and the second plasma split flow 512 flows to the second side edge 612 and performs heat treatment on the surface of the second side edge 612 at the same time.

Based on the foregoing, the present disclosure provides an apparatus for surface heat treatment with plasma and a method for using the device. By utilizing the specially designed first flow channel, second flow channel, third flow channel and slit, the plasma air flow is diverted in order to carry out symmetric or asymmetric heat treatment on the edge surfaces of the workpiece at the same time, and form an outer cover on the edge of the workpiece, which provides the function of preventing the heat from escaping and reducing the energy consumption.

Although the disclosure has been disclosed in the form of embodiments, it is not intended to limit the present disclosure. Anyone with general knowledge in the field of technology may make some changes and modifications without departing from the spirit and scope of the present disclosure, and therefore the scope of protection of the disclosure shall be subject to the scope of the patent application attached hereto.

What is claimed is:

1. An apparatus for proceeding surface heat treatment by plasma, comprising:
a body;
a first flow channel, provided in the body and having a first end and a second end relatively parallel to a first axis, wherein the first end penetrates through the body for connecting to a plasma generation source;
a second flow channel, provided in the body and having a third end and a fourth end relatively parallel to the first axis, wherein the third end is connected with the second end, an inner diameter of the second flow channel is larger than an inner diameter of the second end, the fourth end does not penetrate through the body, and a projection range of the first flow channel parallel to the first axis falls within a projection range of the second flow channel parallel to the first axis;
a third flow channel, provided in the body and having a fifth end and a sixth end relatively parallel to a second axis, the fifth end is connected with the second flow channel, the sixth end penetrates through the body, an included angle is formed between the second axis and the first axis, the included angle is ≥0 degrees, and the first flow channel, the second flow channel, and the third flow channel form a continuous channel; and
a slit, inserted into the body from a surface with the sixth end parallel to the second axis and reaching a depth into the second flow channel, wherein the slit is parallel to the third axis and penetrates through the relative two surfaces of the body, the third axis and the first axis are perpendicular to each other, a projection range of the slit parallel to the third axis falls within a projection range of the third flow channel parallel to the third axis, the slit is formed by a first inner wall and a second inner wall parallel with each other, an inclination angle of the first inner wall and the second inner wall is parallel to the second axis, a width of the slit is formed between the first inner wall and the second inner wall, the slit allows a workpiece to enter the slit parallel to the third axis.

2. The apparatus according to claim 1, wherein a relationship between a width of the slit and a thickness of the workpiece is: (the width of the slit)>(the thickness of the workpiece+1 mm).

3. The apparatus according to claim 1, wherein an inner diameter of the third flow channel is greater than a width of the slit.

4. The apparatus according to claim 1, wherein a relationship between an inner diameter of the third flow channel, an inner diameter of the second flow channel and an inner diameter of the second end of the first flow channel is: (inner diameter of the third flow channel)=(inner diameter of the second flow channel)>( inner diameter of the second end+2 mm).

5. The apparatus according to claim 1, wherein an inner diameter of the second end is 2 mm to 6 mm.

6. The apparatus according to claim 1, wherein an inner diameter of the first end is greater than an inner diameter of the second end, and the first flow channel is tapered.

7. The apparatus according to claim 1, wherein the included angle ranges from 0 degrees to 90 degrees.

8. The apparatus according to claim 1, wherein a center of a projection range of the slit parallel to the second axis falls on a center of a projection range of the third flow channel parallel to the second axis, and a center of a projection range of the slit parallel to the third axis falls on a center of a projection range of the third flow channel parallel to the third axis.

9. The apparatus according to claim 1, wherein the body comprises:
a first portion, wherein the first flow channel is provided in the first portion, a first recess portion is provided on two relative sides of the first portion, and a first convex portion is formed between the two first recess portions; and
a second portion, wherein the second flow channel, the third flow channel and the slit are provided in the second portion, a second convex portion is provided on two relative sides of the second portion, a second recess portion is formed between the two second convex portions, the first convex portion is fitted with the second recess portion, and each first recess portion is fitted with a second convex portion and screwed with at least one bolt.

10. A method for utilizing the apparatus according to claim 1, comprising:
the workpiece is carried through the slit, wherein the edge to be processed of the workpiece is located in the second flow channel, and the edge to be processed has a first side edge and a second side edge relatively;
a plasma air flow is provided by the plasma generation source to enter the first flow channel from the first end, then enters the second flow channel and flows to the edge of the workpiece;
after the plasma air flow contacts the workpiece, it is split into a first plasma split flow and a second plasma split flow; and
the first plasma split flow flows to the first side edge and performs heat treatment on a surface of the first side edge, and the second plasma split flow flows to the second side edge and performs heat treatment on the second side edge at the same time.
